(19) United States
(12) Patent Application Publication
(10) Pub. No.: US 2024/0322797 A1
(43) Pub. Date: Sep. 26, 2024

(54) SEMICONDUCTOR DEVICE

(71) Applicant: LAPIS Technology Co., Ltd., Yokohama (JP)

(72) Inventor: Takashi TOMITA, Yokohama (JP)

(73) Assignee: LAPIS Technology Co., Ltd., Yokohama (JP)

(21) Appl. No.: 18/605,854

(22) Filed: Mar. 15, 2024

(30) Foreign Application Priority Data
Mar. 22, 2023 (JP) 2023-045968

(51) Int. Cl. H03K 3/012

(52) U.S. Cl. CPC H03K 3/012

(57) ABSTRACT

A semiconductor device includes a reference voltage generation portion, generating a reference voltage; a bias current supply portion, including a first current supply portion and a second current supply portion and supplying a bias current to an analog circuit; and a controller, comparing a power supply voltage supplied to the semiconductor device with a set first threshold voltage based on the reference voltage and controlling the bias current supply portion such that when the power supply voltage is higher than the first threshold voltage, only a current supplied from the first current supply portion is output as the bias current, and when the power supply voltage is lower than the first threshold voltage, a current supplied from the first current supply portion and a current supplied from the second current supply portion are combined and output as the bias current.

### CROSS-REFERENCE TO RELATED APPLICATION

This application claims priority under 35 USC 119 from Japanese Patent application No. 2023-045968 filed on Mar. 22, 2023, the disclosure of which is incorporated by reference herein.

### BACKGROUND

### Technical Field

The disclosure relates to a semiconductor device.

### Description of Related Art

Patent Document 1 (Japanese Patent Application Laid-Open (JP-A) No. 2009-145492) describes a display driving device for driving a liquid crystal display device.

In recent years, the resolution of display devices such as liquid crystal display devices has been increasing, and the amount of video data processed by display driving devices for driving display devices has increased accordingly. Thus, the current consumption in the semiconductor devices that constitute the display driving device is increasing, and there is a demand for reducing the current consumption in the semiconductor devices.

In the circuit design of a semiconductor device, the operating conditions are a combination of the recommended operating conditions range of the semiconductor device and the characteristic changing range due to the manufacturing variation of the semiconductor device, and it is necessary to enable the circuit to operate under all combinations of operating conditions.

The operating conditions of a semiconductor device include the standard operating condition, the operating condition that facilitates high-speed operation, and the operating condition that makes high-speed operation difficult. In the circuit design of a semiconductor device, the semiconductor device must be designed to supply current with a margin to operate the circuit even under an operating condition that makes high-speed operation difficult, resulting in excessive current consumption due to excessive margins under the standard operating condition.

In view of the above circumstances, the disclosure may provide a semiconductor device that is capable of operating under an operating condition that makes high-speed operation difficult and that has low current consumption under the standard operating condition.

### SUMMARY

A first semiconductor device of the disclosure includes: a reference voltage generation portion, generating a reference voltage; a bias current supply portion, including a first current supply portion and a second current supply portion and supplying a bias current to an analog circuit; and a controller, comparing a power supply voltage supplied to the semiconductor device with a set first threshold voltage based on the reference voltage and controlling the bias current supply portion such that when the power supply voltage is higher than the first threshold voltage, only a current supplied from the first current supply portion is output as the bias current, and when the power supply voltage is lower than the first threshold voltage, a current supplied from the first current supply portion and a current supplied from the second current supply portion are combined and output as the bias current.

A second semiconductor device of the disclosure includes: a reference voltage generation portion, generating a reference voltage; a bias current supply portion, including a first current supply portion and a third current supply portion and supplying a bias current to an analog circuit; and a controller, comparing a gate threshold voltage of a transistor provided in the semiconductor device with a set second threshold voltage based on the reference voltage and controlling the bias current supply portion such that when the gate threshold voltage is lower than the second threshold voltage, only a current supplied from the first current supply portion is output as the bias current, and when the gate threshold voltage is higher than the second threshold voltage, a current supplied from the first current supply portion and a current supplied from the third current supply portion are combined and output as the bias current.

### BRIEF DESCRIPTION OF THE DRAWINGS

FIG. 1 is a schematic configuration diagram showing the overall configuration of a liquid crystal display device provided with a source driver according to the first embodiment of the disclosure.

FIG. 2 is a block diagram showing a schematic configuration of a part of the source driver according to the first embodiment of the disclosure.

FIG. 3 is a schematic configuration diagram of the bias circuit according to the first embodiment of the disclosure.

FIG. 4 is a schematic configuration diagram of the power supply voltage detection circuit according to the first embodiment of the disclosure.

FIG. 5 is a schematic configuration diagram of the bias circuit according to the second embodiment of the disclosure.

FIG. 6 is a schematic configuration diagram of the power supply voltage detection circuit according to the second embodiment of the disclosure.

FIG. 7 is a schematic configuration diagram of the bias circuit according to the third embodiment of the disclosure.

### DESCRIPTION OF THE EMBODIMENTS

By using the display driving device of the disclosure, a semiconductor device that is capable of operating under an operating condition that makes high-speed operation difficult and that has low current consumption under the standard operating condition is provided.

### First Embodiment

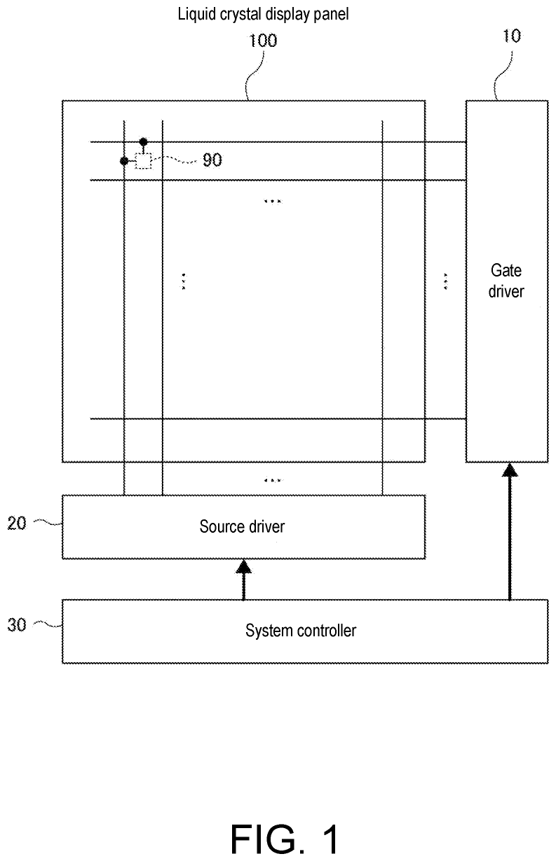

Hereinafter, the embodiments of the disclosure are described with reference to the drawings. FIG. 1 is a schematic configuration diagram showing the overall configuration of a liquid crystal display device provided with a source driver 20 according to the first embodiment of the disclosure.

As shown in FIG. 1, the liquid crystal display device according to this embodiment includes a liquid crystal display panel 100, a gate driver 10, a source driver 20, and a system controller 30.

The liquid crystal display panel 100 includes liquid crystal pixels 90 arranged in a matrix, multiple scanning lines extending in row directions of the matrix, and multiple signal lines extending in column directions of the matrix.

The gate driver 10 sequentially applies a scanning signal to each scanning line to set the scanning lines in a selected state based on a vertical control signal supplied from the system controller 30, which is described later.

The source driver 20 supplies the display signal voltage corresponding to the display data provided by the system controller 30 via the signal lines to each liquid crystal pixel 90 selected by the gate driver 10, based on the horizontal control signal supplied from the system controller 30, which is described later.

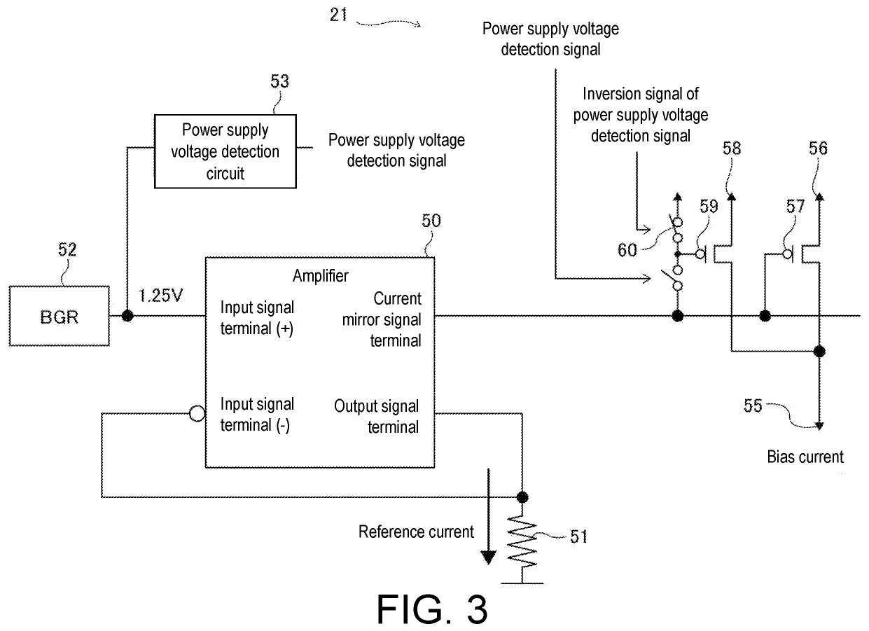

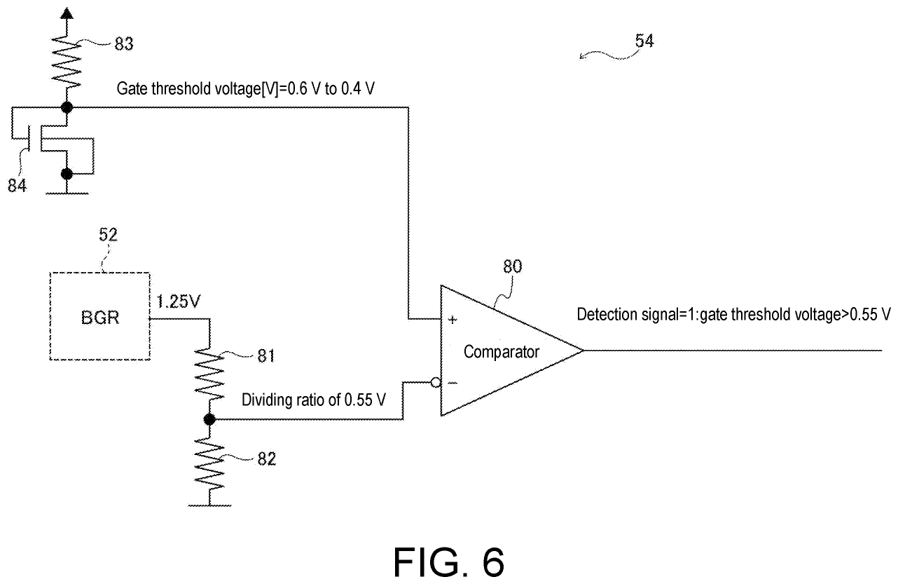

The system controller 30 generates the vertical control signal and the horizontal control signal based on a system clock pclk (see FIG. 3 and FIG. 6), and by supplying the same to each of the gate driver 10 and the source driver 20, the display signal voltage is applied to the liquid crystal pixels 90 at a predetermined timing to control the display of the desired image information on the liquid crystal display panel 100.

That is, the system controller 30, based on the display data supplied externally, generates various control signals for displaying the desired image information on the liquid crystal display panel 100 and outputs the same to the gate driver 10 and the source driver 20.

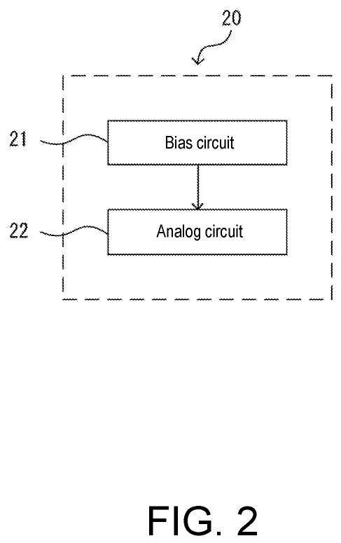

FIG. 2 is a block diagram showing a schematic configuration of a part of the source driver 20. As shown in FIG. 2, the source driver 20 includes a bias circuit 21 and an analog circuit 22. The bias circuit 21 is a circuit that supplies a bias current necessary for the operation of the analog circuit 22. The source driver 20 is configured by a semiconductor integrated circuit such as an integrated circuit (IC) or a large scale integration (LSI), and is an example of the semiconductor device in the technology of the disclosure.

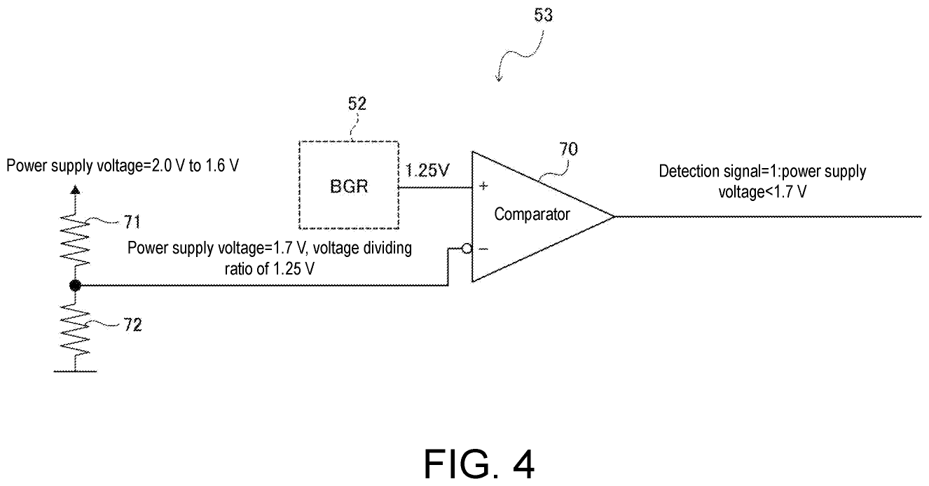

FIG. 3 is a schematic configuration diagram of the bias circuit 21. FIG. 4 is a schematic configuration diagram of the power supply voltage detection circuit 53.

As shown in FIG. 3, the bias circuit 21 includes an amplifier 50, a resistor 51, a bandgap reference (BGR) 52, a power supply voltage detection circuit 53, a bias current output portion 55, a first current supply portion 56, a P-channel metal-oxide semiconductor (PMOS) transistor 57, a second current supply portion 58, a PMOS transistor 59, and a complementary metal-oxide-semiconductor (CMOS) 60. The first current supply portion 56 and the second current supply portion 58 configure the bias current supply portion that supplies the bias current to the analog circuit 22.

The amplifier 50 outputs the reference current based on the reference voltage input from the BGR 52. Further, the amplifier 50 supplies a current equal to the reference current to the first current supply portion 56 and the second current supply portion 58 using a current mirror circuit (not shown). The amplifier 50 is an example of the current generation portion in the technology of the disclosure. Further, the amplifier 50 includes a current mirror signal terminal and outputs a control signal for controlling the PMOS transistors 57 and 59, which are described later.

The BGR 52 is a circuit that generates an absolute reference voltage that is independent of temperature or process. The BGR 52 is an example of the reference voltage generation portion in the technology of the disclosure.

The power supply voltage detection circuit 53 is a circuit that compares a power supply voltage supplied to the source driver 20 with a set first threshold voltage based on the reference voltage and controls the bias current supply portion such that when the power supply voltage is higher than the first threshold voltage, only a current supplied from the first current supply portion 56 is output as the bias current, and when the power supply voltage is lower than the first threshold voltage, a current supplied from the first current supply portion 56 and a current supplied from the second current supply portion 58 are combined and output as the bias current. The power supply voltage detection circuit 53 is an example of the controller in the technology of the disclosure. Specifically, as shown in FIG. 4, the power supply voltage detection circuit 53 includes a comparator 70 and two resistors 71 and 72.

The method of comparing the power supply voltage supplied to the source driver 20 with the set first threshold voltage based on the reference voltage is not particularly limited and may be in various forms.

In this embodiment, as an example, the first threshold voltage is set to 1.7 V. Further, the BGR 52 outputs a voltage of 1.25 V as the reference voltage. Further, it is assumed that the power supply voltage is expected to fluctuate in the range of 2.0 V to 1.6 V. Further, the voltage for evaluation generated using the power supply voltage is the voltage obtained by dividing the power supply voltage using the two resistors 71 and 72, whose resistance values are set to be 1.25 V at the connection point of the two resistors 71 and 72 when the power supply voltage is 1.7 V.

The comparator 70 compares the reference voltage with the voltage for evaluation; when the reference voltage is higher, “1 (power supply voltage)” is output as the detection signal, and when the voltage for evaluation generated using the power supply voltage is higher, “0 (ground potential)” is output as the detection signal.

Thus, when the power supply voltage is higher than the first threshold voltage of 1.7 V, “0” is output from the power supply voltage detection circuit 53, and when the power supply voltage is lower than the first threshold voltage of 1.7 V, “1” is output from the power supply voltage detection circuit 53.

The PMOS transistor 57 has the source connected to the first current supply portion 56, the drain connected to the bias current output portion 55, and the gate connected to the current mirror signal terminal of the amplifier 50. The PMOS transistor 57 functions as a switch that turns on/off the conduction between the source and the drain based on the signal input from the current mirror signal terminal.

The PMOS transistor 59 has the source connected to the second current supply portion 58, the drain connected to the bias current output portion 55, and the gate connected to the current mirror signal terminal of the amplifier 50 through the CMOS 60. The PMOS transistor 59 functions as a switch that turns on/off the conduction between the source and the drain based on the signal input from the current mirror signal terminal through the CMOS 60.

The CMOS 60 functions as a switch that turns on/off the conduction between the current mirror signal terminal of the amplifier 50 and the gate of the PMOS transistor 59 based on the signal output from the power supply voltage detection circuit 53. When the CMOS 60 is in the off state, the PMOS transistor 59 is in the off state regardless of the state of the signal input from the current mirror signal terminal.

Next, the operation of the bias circuit 21 is described.

As mentioned above, the power supply voltage detection circuit 53 outputs “0” when the power supply voltage is higher than 1.7 V and outputs “1” when the power supply voltage is lower than 1.7 V. Since the comparator 70 included in the power supply voltage detection circuit 53 operates at low speed, the current consumption is low.

When the bias current is output from the bias current output portion 55, a control signal for turning on the PMOS transistors 57 and 59 is output from the current mirror signal terminal of the amplifier 50.

In this state, when the signal output from the power supply voltage detection circuit 53 is “0”, that is, when the power supply voltage is higher than 1.7 V, the CMOS 60 is turned off, and this causes the PMOS transistor 59 to be turned off. As a result, the bias current output portion 55 is supplied only with the current from the first current supply portion 56.

It should be noted that the current from the first current supply portion 56 is a bias current sufficient for the analog circuit 22 to operate at high speed under the standard operating condition.

Further, when the signal output from the power supply voltage detection circuit 53 is “1”, that is, when the power supply voltage is lower than 1.7 V, the CMOS 60 is turned on, and this causes the PMOS transistor 59 to be turned on. As a result, the bias current output portion 55 is supplied with a current obtained by combining the current from the first current supply portion 56 and the current from the second current supply portion 58.

It should be noted that the current obtained by combining the current from the first current supply portion 56 and the current from the second current supply portion 58 is a bias current sufficient for the analog circuit 22 to operate at high speed under the operation condition in which the power supply voltage is low.

As described above, in the source driver 20 of this embodiment, when the power supply voltage is low, the bias current is increased to enable high-speed operation, and when the power supply voltage is not low, the bias current may be suppressed to reduce current consumption. It should be noted that multiple systems of the bias current output portion 55 may be provided within the bias circuit 21.

### Second Embodiment

Next, the source driver 20 of the second embodiment is described. The source driver 20 of this embodiment differs in the configuration of the bias circuit 21A compared to the bias circuit 21 of the first embodiment. In the bias circuit 21A of this embodiment, the same components as those of the bias circuit 21 of the first embodiment are given the same reference numbers, and the description is omitted unless particularly necessary.

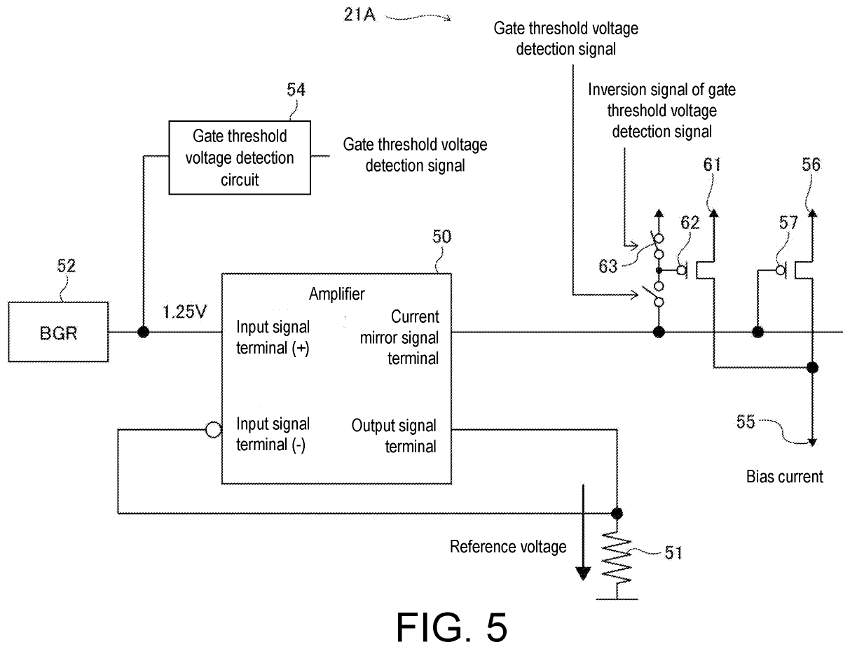

FIG. 5 is a schematic configuration diagram of the bias circuit 21A. FIG. 6 is a schematic configuration diagram of the power supply voltage detection circuit.

As shown in FIG. 5, the bias circuit 21A includes an amplifier 50, a resistor 51, a BGR 52, a gate threshold voltage detection circuit 54, a bias current output portion 55, a first current supply portion 56, a PMOS transistor 57, a third current supply portion 61, a PMOS transistor 62, and a CMOS 63. The first current supply portion 56 and the third current supply portion 61 configure the bias current supply portion that supplies the bias current to the analog circuit 22.

The amplifier 50 outputs the reference current based on the reference voltage input from the BGR 52. Further, the amplifier 50 supplies a current equal to the reference current to the first current supply portion 56 and the third current supply portion 61 using a current mirror circuit (not shown). Further, the amplifier 50 includes a current mirror signal terminal and outputs a control signal for controlling the PMOS transistors 57 and 62, which are described later.

The gate threshold voltage detection circuit 54 is a circuit that compares a gate threshold voltage of the transistor 84 (see FIG. 6) provided in the source driver 20 with a set second threshold voltage based on the reference voltage and controls the bias current supply portion such that when the gate threshold voltage is lower than the second threshold voltage, only a current supplied from the first current supply portion 56 is output as the bias current, and when the gate threshold voltage is higher than the second threshold voltage, a current supplied from the first current supply portion 56 and a current supplied from the third current supply portion 61 are combined and output as the bias current. The gate threshold voltage detection circuit 54 is an example of the controller in the technology of the disclosure. Specifically, as shown in FIG. 6, the gate threshold voltage detection circuit 54 includes a comparator 80, three resistors 81, 82, and 83, and an N-channel metal-oxide semiconductor (NMOS) transistor 84.

Although the source driver 20 includes multiple transistors, the characteristics of the transistors provided in the source driver 20 are uniformly determined as a whole by the conditions at the time of manufacturing the source driver 20. Thus, the characteristics of the dedicated transistor 84 to be compared in the gate threshold voltage detection circuit 54 are considered to be substantially equivalent to the characteristics of the other transistors included in the source driver 20.

The method of comparing the gate threshold voltage of the transistor 84 provided in the source driver 20 with the set second threshold voltage based on the reference voltage is not particularly limited and may be in various forms.

In this embodiment, as an example, the second threshold voltage is set to 0.55 V. Further, the BGR 52 outputs a voltage of 1.25 V as the reference voltage. Further, the second threshold voltage is generated by dividing the reference voltage using the two resistors 81 and 82, whose resistance values are set to be 0.55 V at the connection point of the two resistors 81 and 82 when the reference voltage is applied. Further, it is assumed that the gate threshold voltage of the NMOS transistor 84 is expected to fluctuate in the range of 0.6 V to 0.4 V.

The drain and the gate of the NMOS transistor 84 are connected, and when the resistance value of the resistor 83 is sufficiently high (e.g., several hundred k to several M [Ω]), the gate threshold voltage may be detected at the connection point between the resistor 83 and the drain and the gate of the NMOS transistor 84.

The comparator 80 compares the second threshold voltage with the gate threshold voltage; when the gate threshold voltage is higher, “1 (power supply voltage)” is output as the detection signal, and when the second threshold voltage is higher, “0 (ground potential)” is output as the detection signal.

Thus, when the gate threshold voltage is lower than 0.55 V, “0” is output from the gate threshold voltage detection circuit 54, and when the gate threshold voltage is higher than 0.55 V, “1” is output from the gate threshold voltage detection circuit 54.

The PMOS transistor 62 has the source connected to the third current supply portion 61, the drain connected to the bias current output portion 55, and the gate connected to the current mirror signal terminal of the amplifier 50 through the CMOS 63. The PMOS transistor 62 functions as a switch that turns on/off the conduction between the source and the drain based on the signal input from the current mirror signal terminal through the CMOS 63.

The CMOS 63 functions as a switch that turns on/off the conduction between the current mirror signal terminal of the amplifier 50 and the gate of the PMOS transistor 62 based on the signal output from the gate threshold voltage detection circuit 53. When the CMOS 63 is in the off state, the PMOS transistor 62 is in the off state regardless of the state of the signal input from the current mirror signal terminal.

Next, the operation of the bias circuit 21A is described.

As mentioned above, the gate threshold voltage detection circuit 54 outputs “0” when the gate threshold voltage is lower than 0.55 V and outputs “1” when the gate threshold voltage is higher than 0.55 V. Since the comparator 80 included in the gate threshold voltage detection circuit 54 operates at low speed, the current consumption is low.

When the bias current is output from the bias current output portion 55, a control signal for turning on the PMOS transistors 57 and 62 is output from the current mirror signal terminal of the amplifier 50.

In this state, when the signal output from the gate threshold voltage detection circuit 54 is “0”, that is, when the gate threshold voltage is lower than 0.55 V, the CMOS 63 is turned off, and this causes the PMOS transistor 62 to be turned off. As a result, the bias current output portion 55 is supplied only with the current from the first current supply portion 56.

It should be noted that the current from the first current supply portion 56 is a bias current sufficient for the analog circuit 22 to operate at high speed under the standard operating condition.

Further, when the signal output from the gate threshold voltage detection circuit 54 is “1”, that is, when the gate threshold voltage is higher than 0.55 V, the CMOS 63 is turned on, and this causes the PMOS transistor 62 to be turned on. As a result, the bias current output portion 55 is supplied with a current obtained by combining the current from the first current supply portion 56 and the current from the third current supply portion 61. It should be noted that the current obtained by combining the current from the first current supply portion 56 and the current from the third current supply portion 61 is a bias current sufficient for the analog circuit 22 to operate at high speed under the operation condition in which the gate threshold voltage is high.

As described above, in the source driver 20 of this embodiment, when the gate threshold voltage is high, the bias current is increased to enable high-speed operation, and when the gate threshold voltage is not high, the bias current may be suppressed to reduce current consumption. It should be noted that multiple systems of the bias current output portion 55 may be provided within the bias circuit 21A.

### Third Embodiment

Next, the source driver 20 of the third embodiment is described. In the source driver 20 of this embodiment, the configuration of the bias circuit 21B is a combination of the bias circuit 21 of the first embodiment and the bias circuit 21A of the second embodiment. In the bias circuit 21B of this embodiment, the same components as those of the bias circuit 21 of the first embodiment and the bias circuit 21A of the second embodiment are given the same reference numbers, and the description is omitted unless particularly necessary.

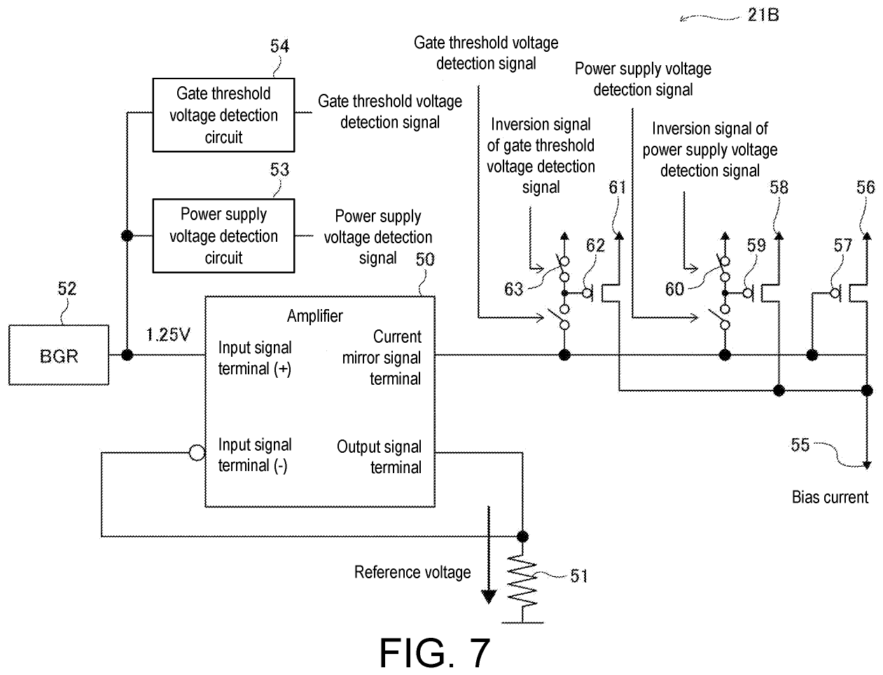

FIG. 7 is a schematic configuration diagram of the bias circuit 21B. As shown in FIG. 7, the bias circuit 21B includes an amplifier 50, a resistor 51, a BGR 52, a power supply voltage detection circuit 53, a gate threshold voltage detection circuit 54, a bias current output portion 55, a first current supply portion 56, a PMOS transistor 57, a second current supply portion 58, a PMOS transistor 59, a CMOS 60, a third current supply portion 61, a PMOS transistor 62, and a CMOS 63. The first current supply portion 56, the second current supply portion 58, and the third current supply portion 61 configure the bias current supply portion that supplies the bias current to the analog circuit 22.

Next, the operation of the bias circuit 21B is described.

When the bias current is output from the bias current output portion 55, a control signal for turning on the PMOS transistors 57, 59, 62 is output from the current mirror signal terminal of the amplifier 50.

As mentioned above, the power supply voltage detection circuit 53 outputs “0” when the power supply voltage is higher than 1.7 V and outputs “1” when the power supply voltage is lower than 1.7V. Since the comparator 70 included in the power supply voltage detection circuit 53 operates at low speed, the current consumption is low.

When the signal output from the power supply voltage detection circuit 53 is “0”, that is, when the power supply voltage is higher than 1.7 V, the CMOS 60 is turned off, and this causes the PMOS transistor 59 to be turned off. As a result, the bias current output portion 55 is supplied only with the current from the first current supply portion 56.

It should be noted that the current from the first current supply portion 56 is a bias current sufficient for the analog circuit 22 to operate at high speed under the standard operating condition.

Further, when the signal output from the power supply voltage detection circuit 53 is “1”, that is, when the power supply voltage is lower than 1.7 V, the CMOS 60 is turned on, and this causes the PMOS transistor 59 to be turned on. As a result, the bias current output portion 55 is supplied with a current obtained by combining the current from the first current supply portion 56 and the current from the second current supply portion 58.

It should be noted that the current obtained by combining the current from the first current supply portion 56 and the current from the second current supply portion 58 is a bias current sufficient for the analog circuit 22 to operate at high speed under the operation condition in which the power supply voltage is low.

As mentioned above, the gate threshold voltage detection circuit 54 outputs “0” when the gate threshold voltage is lower than 0.55 V and outputs “1” when the gate threshold voltage is higher than 0.55 V. Since the comparator 80 included in the gate threshold voltage detection circuit 54 operates at low speed, the current consumption is low.

When the signal output from the gate threshold voltage detection circuit 54 is “0”, that is, when the gate threshold voltage is lower than 0.55 V, the CMOS 63 is turned off, and this causes the PMOS transistor 62 to be turned off. As a result, the bias current output portion 55 is supplied only with the current from the first current supply portion 56.

It should be noted that the current from the first current supply portion 56 is a bias current sufficient for the analog circuit 22 to operate at high speed under the standard operating condition.

Further, when the signal output from the gate threshold voltage detection circuit 54 is “1”, that is, when the gate threshold voltage is higher than 0.55 V, the CMOS 63 is turned on, and this causes the PMOS transistor 62 to be turned on. As a result, the bias current output portion 55 is supplied with a current obtained by combining the current from the first current supply portion 56 and the current from the third current supply portion 61. It should be noted that the current obtained by combining the current from the first current supply portion 56 and the current from the third current supply portion 61 is a bias current sufficient for the analog circuit 22 to operate at high speed under the operation condition in which the gate threshold voltage is high.

Furthermore, when the power supply voltage is lower than 1.7 V and the gate threshold voltage is higher than 0.55 V, the bias current output portion 55 is supplied with a current obtained by combining the current from the first current supply portion 56, the current from the second current supply portion 58, and the current from the third current supply portion 61.

It should be noted that the current obtained by combining the current from the first current supply portion 56, the current from the second current supply portion 58, and the current from the third current supply portion 61 is a bias current sufficient for the analog circuit 22 to operate at high speed under the operation condition in which the power supply voltage is low and the gate threshold voltage is high.

As described above, the source driver 20 of this embodiment has the effects of the first embodiment and the second embodiment, and is further capable of optimizing the bias current even when the power supply voltage is low and the gate threshold voltage is high. It should be noted that multiple systems of the bias current output portion 55 may be provided within the bias circuit 21B.

The content and drawings described above are detailed descriptions of the parts related to the technology of the disclosure, and are merely examples of the technology of the disclosure. For example, the above description regarding the configuration, function, operation, and effect is an example of the configuration, function, operation, and effect of the parts related to the technology of the disclosure. Thus, unnecessary sections may be deleted, and new elements may be added or substituted for the content and drawings shown above to the extent that it does not depart from the main purpose of the technology of the disclosure. Further, in order to avoid confusion and to facilitate understanding of the parts regarding the technology of the disclosure, in the descriptions and drawings shown above, explanations concerning technical common knowledge, etc. that do not require particular explanation to enable implementation of the technology of the disclosure have been omitted.

What is claimed is:

1. A semiconductor device, comprising:
a reference voltage generation portion, generating a reference voltage;
a bias current supply portion, comprising a first current supply portion and a second current supply portion and supplying a bias current to an analog circuit; and
a controller, comparing a power supply voltage supplied to the semiconductor device with a set first threshold voltage based on the reference voltage and controlling the bias current supply portion such that when the power supply voltage is higher than the first threshold voltage, only a current supplied from the first current supply portion is output as the bias current, and when the power supply voltage is lower than the first threshold voltage, a current supplied from the first current supply portion and a current supplied from the second current supply portion are combined and output as the bias current.

2. The semiconductor device according to claim 1, comprising a current generation portion that generates a reference current using the reference voltage and supplies a current equal to the reference current to each of the first current supply portion and the second current supply portion using a current mirror circuit.

3. The semiconductor device according to claim 1, wherein the bias current supply portion further comprises a third current supply portion, and
the controller compares a gate threshold voltage of a transistor provided in the semiconductor device with a set second threshold voltage based on the reference voltage and controls the bias current supply portion such that when the gate threshold voltage is lower than the second threshold voltage, only a current supplied from the first current supply portion is output as the bias current, and when the gate threshold voltage is higher than the second threshold voltage, a current supplied from the first current supply portion and a current supplied from the third current supply portion are combined and output as the bias current.

4. The semiconductor device according to claim 3, comprising a current generation portion that generates a reference current using the reference voltage and supplies a current equal to the reference current to each of the first current supply portion, the second current supply portion, and the third current supply portion using a current mirror circuit.

5. A semiconductor device, comprising:
a reference voltage generation portion, generating a reference voltage;
a bias current supply portion, comprising a first current supply portion and a third current supply portion and supplying a bias current to an analog circuit; and
a controller, comparing a gate threshold voltage of a transistor provided in the semiconductor device with a set second threshold voltage based on the reference voltage and controlling the bias current supply portion such that when the gate threshold voltage is lower than the second threshold voltage, only a current supplied from the first current supply portion is output as the bias current, and when the gate threshold voltage is higher than the second threshold voltage, a current supplied from the first current supply portion and a current supplied from the third current supply portion are combined and output as the bias current.

6. The semiconductor device according to claim 5, comprising a current generation portion that generates a reference current using the reference voltage and supplies a current equal to the reference current to each of the first current supply portion and the third current supply portion using a current mirror circuit.
